(19) United States
(12) Patent Application Publication
(10) Pub. No.: US 2026/0052934 A1
(43) Pub. Date: Feb. 19, 2026

(54) SUBSTRATE PROCESSING APPARATUS

(71) Applicant: Tokyo Electron Limited, Tokyo (JP)

(72) Inventor: Norihiko AMIKURA, Miyagi (JP)

(73) Assignee: Tokyo Electron Limited, Tokyo (JP)

(21) Appl. No.: 19/366,586

(22) Filed: Oct. 23, 2025

Related U.S. Application Data
(63) Continuation of application No. PCT/JP2024/016054, filed on Apr. 24, 2024.

(30) Foreign Application Priority Data
May 8, 2023 (JP) 2023-076579

(51) Int. Cl. H01L 21/67; H01L 21/677

(52) U.S. Cl. CPC H01L 21/67184; H01L 21/6719; H01L 21/67196; H01L 21/67742

(57) ABSTRACT

There is provided a substrate processing apparatus for processing a substrate, the substrate processing apparatus including: a first processing module group including a plurality of first processing modules; a plurality of first transfer modules, each first transfer module being connected to a respective one of the plurality of first processing modules; a second processing module group including a plurality of second processing modules; and a plurality of second transfer modules, each second transfer module being connected to a respective one of the plurality of second processing modules. The plurality of first transfer modules are disposed above the plurality of second processing modules, and the plurality of second transfer modules are disposed below the plurality of first processing modules.

### CROSS-REFERENCE TO RELATED APPLICATIONS

This application is a bypass continuation application of International Application No. PCT/JP2024/016054 having an international filing date of Apr. 24, 2024, and designating the United States, the international application being based upon and claiming the benefit of priority from Japanese Patent Application No. 2023-076579 filed on May 8, 2023, the entire contents of each are incorporated herein by reference.

### TECHNICAL FIELD

The present disclosure relates to a substrate processing apparatus.

### BACKGROUND

PTL 1 discloses a substrate processing apparatus in which processing modules are connected to a vacuum transfer module. An example of the substrate processing apparatus has a configuration in which a first vacuum transfer module and a second vacuum transfer module are coupled, and six processing modules are connected to each vacuum transfer module.

### CITATION LIST

### Patent Documents

PTL 1: JP2022-104056A

### SUMMARY

According to the technique of the present disclosure, the productivity per unit area is improved while a height of the substrate processing apparatus is restricted.

An aspect of the present disclosure is a substrate processing apparatus for processing substrates, the substrate processing apparatus including: a first processing module group including one or more first processing modules; a first transfer module connected to the first processing module; a second processing module group including one or more second processing modules; and a second transfer module connected to the second processing module. The first transfer module is disposed above the second processing module, and the second transfer module is disposed below the first processing module.

According to the present disclosure, the productivity per unit area can be improved while the height of the substrate processing apparatus is restricted.

### BRIEF DESCRIPTION OF DRAWINGS

FIG. 1 is a plan view illustrating a schematic configuration of a wafer processing apparatus according to an embodiment.

FIG. 2 is a perspective view illustrating a schematic configuration of the wafer processing apparatus according to the present embodiment.

FIG. 3 is a perspective view illustrating a schematic configuration of the wafer processing apparatus according to the present embodiment.

FIG. 4 is a perspective view illustrating a schematic configuration of a composite module.

FIG. 5 is an illustrative diagram schematically illustrating a configuration of both end surfaces of a transfer chamber.

FIG. 6 is a plan view illustrating a schematic configuration of a transfer unit.

FIG. 7 is a view illustrating a state of producing the wafer processing apparatus.

FIG. 8 is an illustrative diagram illustrating a comparison between the wafer processing apparatus according to the present embodiment and a wafer processing apparatus in the related art.

FIG. 9 is a plan view illustrating a schematic configuration of a wafer processing apparatus according to one or more embodiments.

FIG. 10 is a front view illustrating a schematic configuration of a loading and unloading module.

FIG. 11 is a side view illustrating the schematic configuration of the loading and unloading module.

FIG. 12 is a side view illustrating the schematic configuration of the loading and unloading module.

FIG. 13 is a plan view illustrating the schematic configuration of the loading and unloading module.

FIG. 14 is a perspective view illustrating a schematic configuration of a wafer processing apparatus according to one or more embodiments.

FIG. 15 is a plan view illustrating a schematic configuration of the wafer processing apparatus in the related art.

FIG. 16 is an illustrative diagram illustrating an example in which processing modules are stacked in a vertical direction.

### DETAILED DESCRIPTION

In a process of manufacturing a semiconductor device, various processing steps of bringing an inside of a processing module in which a semiconductor wafer (a substrate, hereinafter, simply referred to as a “wafer”) is accommodated into a pressure-reduced (for example, vacuum) state and processing the wafer are performed. These processing steps are performed in a wafer processing apparatus (a substrate processing apparatus) including the processing modules.

The wafer processing apparatus includes, for example, a normal pressure portion (for example, an atmospheric portion) provided with a normal pressure module (for example, an atmospheric module) that processes and transfers the wafer under a normal pressure atmosphere (for example, an atmospheric atmosphere), and a pressure-reduced portion (for example, a vacuum portion) provided with a pressure-reduced module (for example, a vacuum module) that processes and transfers the wafer under a pressure-reduced atmosphere (for example, a vacuum atmosphere). The normal pressure portion and the pressure-reduced portion are integrally connected to each other through a load lock module whose inside can be switched between a normal pressure atmosphere and a pressure-reduced atmosphere.

When designing the wafer processing apparatus, it is known to connect the processing modules to one transfer module in the pressure-reduced portion. For example, as disclosed in PTL 1, two transfer modules are connected as a transfer system.

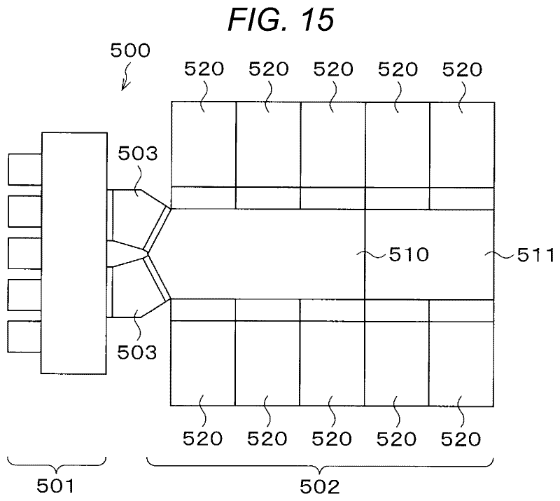

An example of a wafer processing apparatus 500 in the related art will be described with reference to FIG. 15. The wafer processing apparatus 500 has a configuration in which a normal pressure portion 501 and a pressure-reduced portion 502 are connected via two load lock modules 503. The pressure-reduced portion 502 includes a first transfer module 510 and a second transfer module 511. The first transfer module 510 and the second transfer module 511 are coupled in this order from a side of the load lock modules 503. Six processing modules 520 are connected to the first transfer module 510. Four processing modules 520 are connected to the second transfer module 511.

Here, when installing the wafer processing apparatus in a limited space of a factory, the productivity is improved by installing more processing modules. However, for example, when disposing the transfer modules 510 and 511 and the ten processing modules 520 side by side in a horizontal direction as in the wafer processing apparatus 500 illustrated in FIG. 15, the number of processing modules 520 that can be installed in a factory is limited.

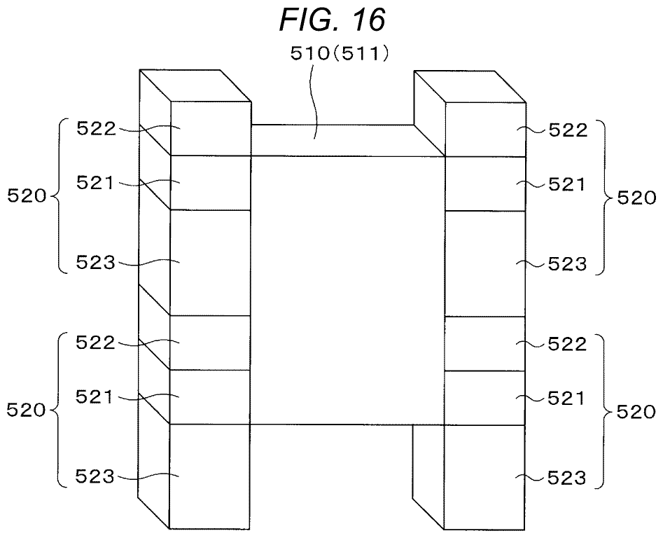

Therefore, for example, when the processing modules 520 are stacked and disposed in a vertical direction as illustrated in FIG. 16, the productivity per unit area can be improved. However, each processing module 520 has a configuration in which a processing chamber 521, an upper equipment unit 522, and a lower equipment unit 523 are stacked, and for example, when two processing modules 520 are stacked, a height of the wafer processing apparatus 500 is increased. In this case, accessibility to equipment above is low, and it is difficult to perform work such as maintenance. In particular, maintenance of heavy equipment or the like is greatly affected.

According to the technique of the present disclosure, the productivity per unit area is improved while a height of the substrate processing apparatus is restricted. Hereinafter, a wafer processing apparatus as a substrate processing apparatus according to the present embodiment will be described with reference to the drawings. The same reference numerals will be given to elements having substantially the same functional configurations throughout the specification and the drawings, and redundant description thereof will be omitted.

### Wafer Processing Apparatus

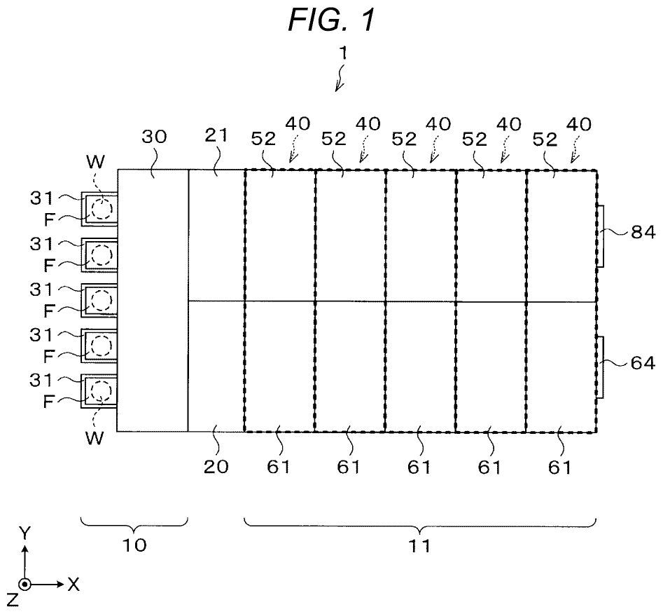

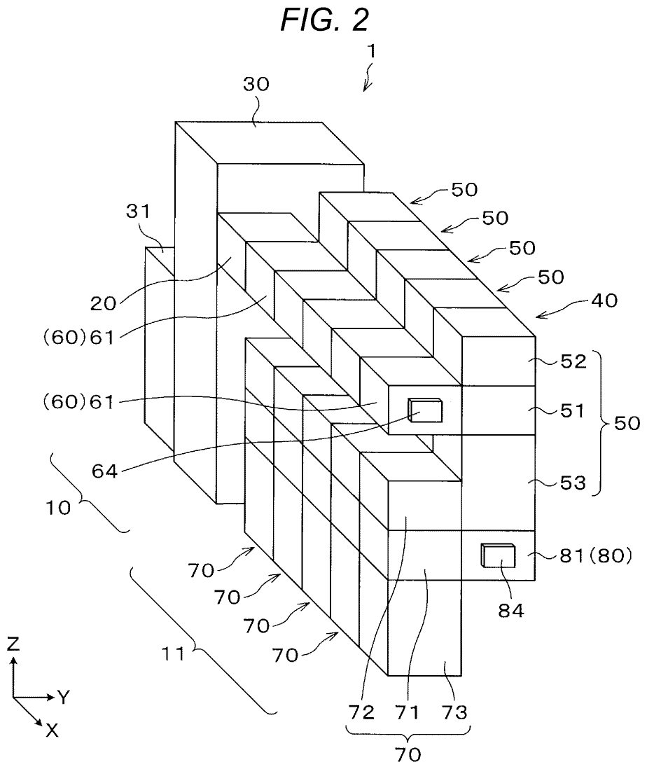

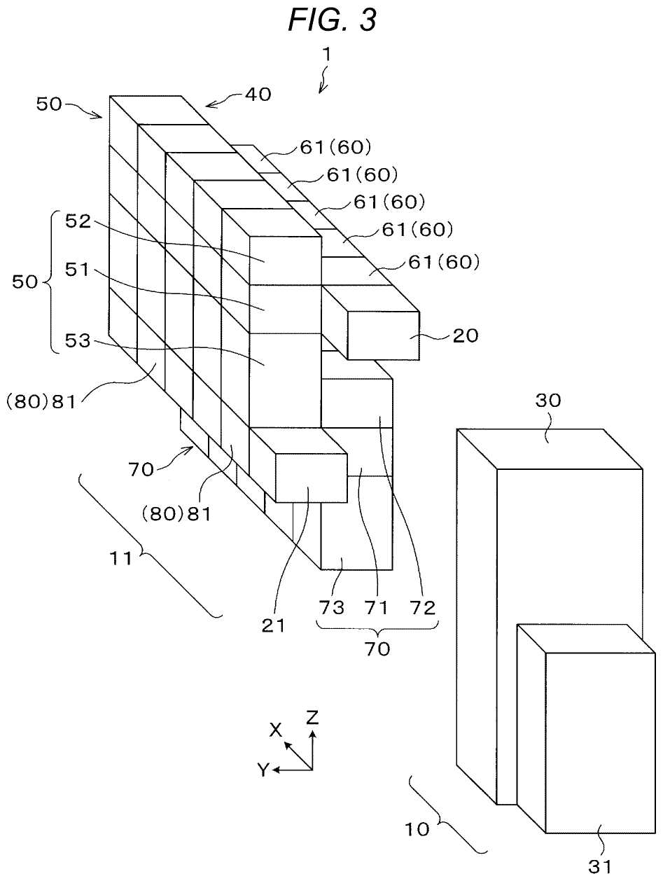

First, a wafer processing apparatus according to the present embodiment will be described. FIG. 1 is a plan view illustrating a schematic configuration of a wafer processing apparatus 1. FIGS. 2 and 3 are perspective views illustrating the schematic configuration of the wafer processing apparatus 1. In order to facilitate the illustration, FIG. 3 illustrates a normal pressure portion 10, a pressure-reduced portion 11, and load lock modules 20 and 21 separately, which are to be described later. In the wafer processing apparatus 1, a wafer W that is a substrate is subjected to plasma processing such as etching processing, film formation processing, and diffusion processing.

As illustrated in FIGS. 1 to 3, the wafer processing apparatus 1 has a configuration in which the normal pressure portion (for example, an atmospheric portion) 10 and the pressure-reduced portion (for example, a vacuum portion) 11 are integrally connected to each other through two load lock modules 20 and 21. The normal pressure portion 10 includes a normal pressure module (for example, an atmospheric module) configured to perform desired processing on the wafer W under a normal pressure atmosphere (for example, an atmospheric atmosphere). The pressure-reduced portion 11 includes a pressure-reduced module (for example, a vacuum module) configured to perform desired processing on the wafer W under a pressure-reduced atmosphere (for example, a vacuum atmosphere).

The load lock modules 20 and 21 couple a loader module 30 to be described later of the normal pressure portion 10 to a composite module 40 to be described later of the pressure-reduced portion 11 via gate valves. Specifically, the first load lock module 20 is coupled to a first transfer module 60 to be described later, and the second load lock module 21 is coupled to a second transfer module 80 to be described later. The load lock modules 20 and 21 are configured to temporarily hold the wafer W. Further, each of the load lock modules 20 and 21 is configured such that an inside thereof can be switched between a normal pressure atmosphere and a pressure-reduced atmosphere.

The normal pressure portion 10 includes the loader module (equipment front end module (EFEM)) 30 provided with a transfer unit of the wafer W, and a load port 31 on which a front opening unified pod (FOUP) F serving as an accommodating portion is placed. The FOUP F can accommodate a plurality of wafers W, for example, 25 wafers W, under a normal pressure atmosphere. An orienter module that adjusts an orientation of the wafer W in a horizontal direction, a buffer module that temporarily stores the plurality of wafers W, and the like may be connected to the loader module 30.

The loader module 30 has a rectangular housing, and an inside of the housing is maintained in a normal pressure atmosphere. The load ports 31, for example, five load ports 31, are arranged side by side on one side surface forming a long side of a housing of the loader module 30 in a Y-axis direction. The load lock modules 20 and 21 are disposed side by side on the other side surface forming the long side of the housing of the loader module 30.

The pressure-reduced portion 11 includes a plurality of, for example, five composite modules 40. The five composite modules 40 are coupled side by side in an X-axis direction from the side of the load lock modules 20 and 21. The X-axis direction is the coupling direction and is a first direction in the present disclosure, and the Y-axis direction is a second direction in the present disclosure. In the following description, an X-axis negative direction side may be referred to as a front side, and an X-axis positive direction side may be referred to as a rear side.

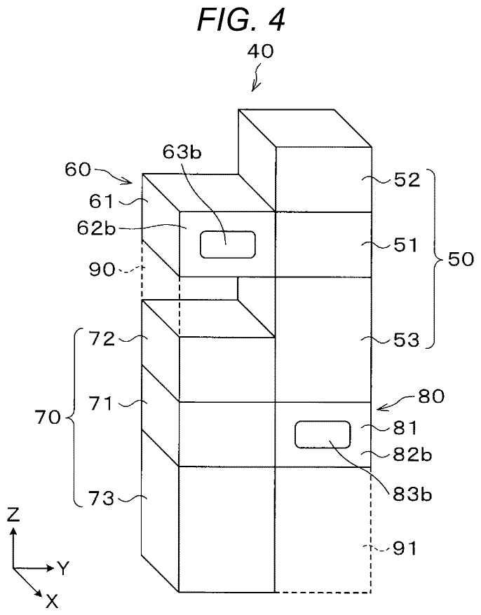

The five composite modules 40 have the same configuration. As illustrated in FIG. 4, the composite module 40 has a configuration in which a first processing module 50, a first transfer module 60, a second processing module 70, and a second transfer module 80 are integrated. The first processing module 50 and the second processing module 70 are also referred to as process modules (PM). The first transfer module 60 and the second transfer module 80 are pressure-reduced transfer modules, and are also referred to as vacuum transfer modules (VTM).

The first processing module 50 includes a first processing chamber 51, a first upper equipment unit 52, and a first lower equipment unit 53. The first upper equipment unit 52, the first processing chamber 51, and the first lower equipment unit 53 are stacked in this order from an upper side.

A processing space for processing the wafer W is formed inside the first processing chamber 51. The first processing chamber 51 is configured to maintain the processing space in a pressure-reduced atmosphere. In the processing space, the wafer W is subjected to plasma processing such as the etching processing, the film formation processing, and the diffusion processing. Further, the processing space is in communication with a transfer space of a first transfer chamber 61 to be described later via a wafer loading and unloading port formed in a side surface of the first processing chamber 51. The wafer loading and unloading port is configured to be opened and closed by using a gate valve.

The first upper equipment unit 52 includes equipment necessary for wafer processing, and includes, for example, electric equipment and a gas supply system. The electric equipment includes, for example, a controller configured to control the first processing module 50. The electric equipment includes, for example, a power source that is a power supply configured to supply power to various types of equipment. The gas supply system includes a gas box, a gas line, and the like. The gas box supplies a gas necessary for the plasma processing into the processing space of the first processing chamber 51. The gas line is a line configured to supply the gas from the gas box to the first processing chamber 51.

The first lower equipment unit 53 includes equipment necessary for wafer processing, and includes, for example, a vacuum system, a generator, and a cooling water supply mechanism. The vacuum system includes a vacuum pump, a vacuum line, and the like. The vacuum pump includes, for example, a dry pump or a turbo molecular pump, and vacuums the processing space of the first processing chamber 51. The vacuum line is a line connecting the vacuum pump and the first processing chamber 51. The cooling water supply mechanism supplies cooling water to an apparatus that requires cooling water.

The second processing module 70 has the same configuration as the first processing module 50, and includes a second processing chamber 71, a second upper equipment unit 72, and a second lower equipment unit 73. The second upper equipment unit 72, the second processing chamber 71, and the second lower equipment unit 73 are stacked in this order from the upper side.

The first transfer module 60 has a first transfer chamber 61. A transfer space for transferring the wafer W is formed inside the first transfer chamber 61. The first transfer chamber 61 is configured to maintain the transfer space in a pressure-reduced atmosphere.

The second transfer module 80 has the same configuration as the first transfer module 60 and has a second transfer chamber 81.

In the composite module 40, the first processing module 50 is provided above the second transfer module 80. Further, the first transfer module 60 is provided above the second processing module 70.

The first processing chamber 51 and the first transfer chamber 61 are connected to each other in the Y-axis direction. A first region 90 that is a spatial region is located between the first transfer chamber 61 and the second upper equipment unit 72, in a Y-axis negative direction of the first lower equipment unit 53. That is, the first transfer chamber 61, the first region 90, the second upper equipment unit 72, the second processing chamber 71, and the second lower equipment unit 73 are provided in this order from the upper side.

The second processing chamber 71 and the second transfer chamber 81 are connected to each other in the Y-axis direction. A second region 91 that is a spatial region is located below the second transfer chamber 81, in a Y-axis positive direction of the second lower equipment unit 73. That is, the first upper equipment unit 52, the first processing chamber 51, the first lower equipment unit 53, the second transfer chamber 81, and the second region 91 are provided in this order from the upper side.

The first region 90 may be located above the first transfer chamber 61, in the Y-axis negative direction of the first upper equipment unit 52. Further, the second region 91 may be located above the second transfer chamber 81, in the Y-axis positive direction of the second upper equipment unit 72. In the illustrated example, although there is no spatial region between the first lower equipment unit 53 and the second transfer chamber 81, the second region 91 may be located between the first lower equipment unit 53 and the second transfer chamber 81.

In a side view, the first lower equipment unit 53 is disposed at a height in the upper first processing module 50, and the second lower equipment unit 73 is disposed at a similar height in the lower second processing module 70.

As illustrated in FIGS. 1 to 3, the five composite modules 40 are coupled side by side in the coupling direction (the X-axis direction) from the side of the load lock modules 20 and 21. In the five composite modules 40, the five first processing modules 50 are disposed side by side in the X-axis direction, and constitute a first processing module group in the present disclosure. That is, the five first processing chambers 51 are disposed side by side in the X-axis direction. Similarly, the five second processing modules 70 are disposed side by side in the X-axis direction, constitute a second processing module group in the present disclosure, and the five second processing chambers 71 are disposed side by side in the X-axis direction.

The five first transfer modules 60 are disposed side by side in the X-axis direction, and constitute a first transfer system in the present disclosure. Similarly, the five second transfer modules 80 are disposed side by side in the X-axis direction, and constitute a second transfer system in the present disclosure.

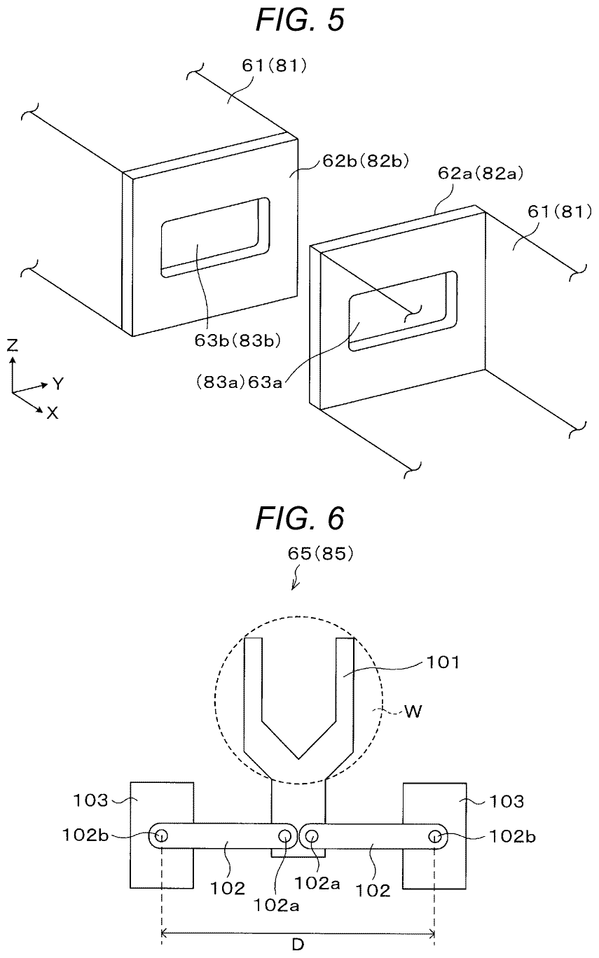

In the first transfer system, as illustrated in FIG. 5, a front end surface (an end surface in the X-axis negative direction) 62a of the first transfer chamber 61 in the coupling direction is a flat surface, and an opening 63a is formed in the front end surface 62a. A rear end surface (an end surface in the X-axis positive direction) 62b of the first transfer chamber 61 in the coupling direction is a flat surface, and an opening 63b is formed in the rear end surface 62b. The openings 63a and 63b have the same shape, and when the first transfer chambers 61 adjacent to each other are directly connected, the openings 63a and 63b are continuous. When the five first transfer chambers 61 are connected, five transfer spaces communicate with each other via the openings 63a and 63b. In the following description, a space formed by the five transfer spaces communicating with each other may be referred to as a first communication transfer space.

A method of connecting the first transfer chambers 61 adjacent to each other can be any method as long as the first transfer chambers 61 can be directly connected to each other. For example, the rear end surface 62b of the first transfer chamber 61 on the front side and the front end surface 62a of the first transfer chamber 61 on the rear side may be fixed by screws. At this time, a periphery of the opening 63a of the front end surface 62a and a periphery of the opening 63b of the rear end surface 62b are sealed.

Further, a first connection module may be provided between the forwardmost first transfer chamber 61 among the five first transfer chambers 61 and the first load lock module 20. An exhaust port is formed in a bottom surface of the first connection module, and the exhaust port is connected to a vacuum pump that includes, for example, a dry pump or a turbo molecular pump. The five first transfer chambers 61 are configured to maintain the first communication transfer space in a pressure-reduced atmosphere by vacuuming the first communication transfer space from the exhaust port. The first connection module may be omitted, and the exhaust port may be formed in the first load lock module 20.

The opening 63b of the rear end surface 62b of the rearmost first transfer chamber 61 among the five first transfer chambers 61 is closed by, for example, a plate 64.

Similarly, in the second transfer system, an opening 83a of a front end surface 82a and an opening 83b of a rear end surface 82b of the second transfer chamber 81 are continuous, the second transfer chambers 81 adjacent to each other are directly connected to each other, and the transfer spaces of the five second transfer chambers 81 communicate with each other.

A second connection module may be provided between the forwardmost second transfer chamber 81 and the second load lock module 21. An exhaust port is formed in a bottom surface of the second connection module, and the exhaust port is connected to a vacuum pump that includes, for example, a dry pump or a turbo molecular pump. The five second transfer chambers 81 are configured to maintain the second communication transfer space in a pressure-reduced atmosphere by vacuuming the second communication transfer space from the exhaust port. The second connection module may be omitted, and the exhaust port may be formed in the second load lock module 21.

The opening 83b of the rear end surface 82b of the rearmost second transfer chamber 81 among the five second transfer chambers 81 is closed by, for example, a plate 84.

As described above, the first transfer chambers 61 adjacent to each other are connected to each other, and the second transfer chambers 81 adjacent to each other are connected to each other, so that the five composite modules 40 are coupled to each other.

A magnetically levitated first transfer unit 65 is provided in the first communication transfer space formed by the five transfer spaces communicating with each other in the five connected first transfer chambers 61. As illustrated in FIG. 6, the first transfer unit 65 includes an end effector 101, two links 102, and two bases 103. The end effector 101 holds the wafer W. Each of the links 102 connects the end effector 101 and the base 103. One end portion of the link 102 is connected to the end effector 101 to be rotatable around a rotation axis 102a in a vertical direction. The other end portion of the link 102 is connected to the base 103 to be rotatable around a rotation axis 102b in the vertical direction. The two links 102 can be extended and retracted while maintaining an orientation of the end effector 101 by changing an interval D between the two rotation axes 102b (the two bases 103). The base 103 is provided with permanent magnets.

A planar motor is provided on a bottom surface of the first communication transfer space. Coils are provided in the planar motor, and a magnetic field is generated by supplying a current to the coils. The base 103 including the permanent magnets is levitated and moves by the magnetic field generated by the coils. That is, the first transfer unit 65 is magnetically levitated above the planar motor and moves above the planar motor. At this time, by controlling a current value of the coils, a position, an orientation, and a levitation amount of the base 103 can be controlled.

The number of the first transfer units 65 provided in the first communication transfer space is not limited. One first transfer unit 65 may be provided, or multiple first transfer units 65 may be provided.

A magnetically levitated second transfer unit 85 is provided in the second communication transfer space formed by the five transfer spaces communicating with each other in the five connected second transfer chambers 81. A configuration of the second transfer unit 85 is the same as the configuration of the first transfer unit 65 illustrated in FIG. 6. A configuration of a bottom surface of the second communication transfer space is also the same as the bottom surface of the first communication transfer space, and the second transfer unit 85 is magnetically levitated and moved. The number of second transfer units 85 provided in the second communication transfer space is not limited. One second transfer unit 85 may be provided, or multiple second transfer units 85 may be provided.

### Method for Producing Wafer Processing Apparatus

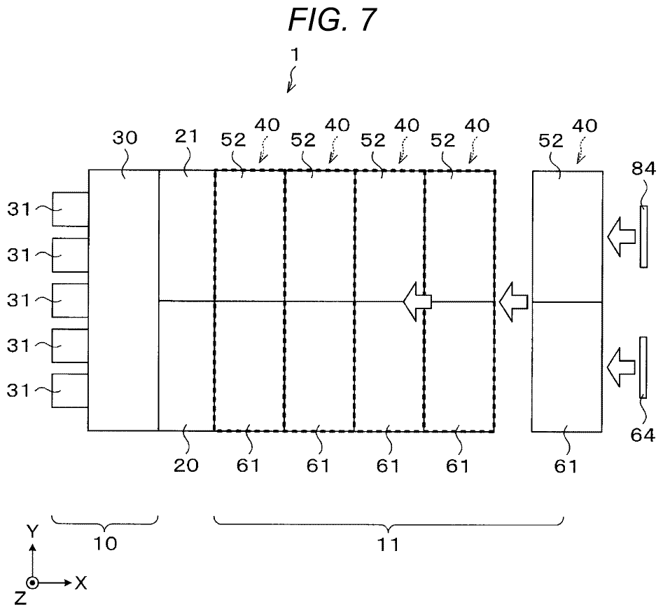

FIG. 7 is a view illustrating a method for producing the wafer processing apparatus 1. As illustrated in FIG. 7, when producing the wafer processing apparatus 1, first, the normal pressure portion 10 and the two load lock modules 20 and 21 are connected.

Next, five composite modules 40 are moved toward the load lock modules 20 and 21, and the five composite modules 40 are coupled to the load lock modules 20 and 21. Specifically, first, the forwardmost first transfer chamber 61 is connected to the first load lock module 20, and the forwardmost second transfer chamber 81 is connected to the second load lock module 21. Subsequently, the next first transfer chamber 61 is connected to the first transfer chamber 61 on the front side, and the next second transfer chamber 81 is connected to the second transfer chamber 81 on the front side, so that the five composite modules 40 are coupled.

Next, the first transfer unit 65 is carried into the first communication transfer space of the five first transfer chambers 61. Thereafter, the opening 63b formed in the rear end surface 62b of the rearmost first transfer chamber 61 is closed by the plate 64. Similarly, the second transfer unit 85 is carried into the second communication transfer space of the five second transfer chambers 81. Thereafter, the opening 83b formed in the rear end surface 82b of the rearmost second transfer chamber 81 is closed by the plate 84. As described above, the wafer processing apparatus 1 is produced.

### Effects of Present Embodiment

According to the embodiment described above, the first processing module group (the first processing modules 50), the first transfer system (the first transfer modules 60), the second processing module group (the second processing modules 70), and the second transfer system (the second transfer modules 80) are provided extending in the X-axis direction independently of each other. The first processing module 50 and the second transfer module 80 are disposed in this order from the upper side, and the first processing module 50 (the first processing chamber 51) and the second transfer module 80 (the second transfer chamber 81) are disposed overlapping each other in a top view. Further, the first transfer module 60 and the second processing module 70 are disposed in this order from the upper side, and the first transfer module 60 (the first transfer chamber 61) and the second processing module 70 (the second processing chamber 71) are disposed overlapping each other in the top view. As described, in the top view, the first transfer system is accommodated in a manner of overlapping the second processing module group, and the second transfer system is accommodated in manner of overlapping the first processing module group. In that case, for example, compared to the case where the transfer system and the processing module group are disposed side by side in the horizontal direction as in the wafer processing apparatus 500 in the related art illustrated in FIG. 15, area (footprint) occupied by the wafer processing apparatus 1 can be reduced while maintaining the transfer performance and the processing performance. As a result, it is possible to improve the productivity per unit area.

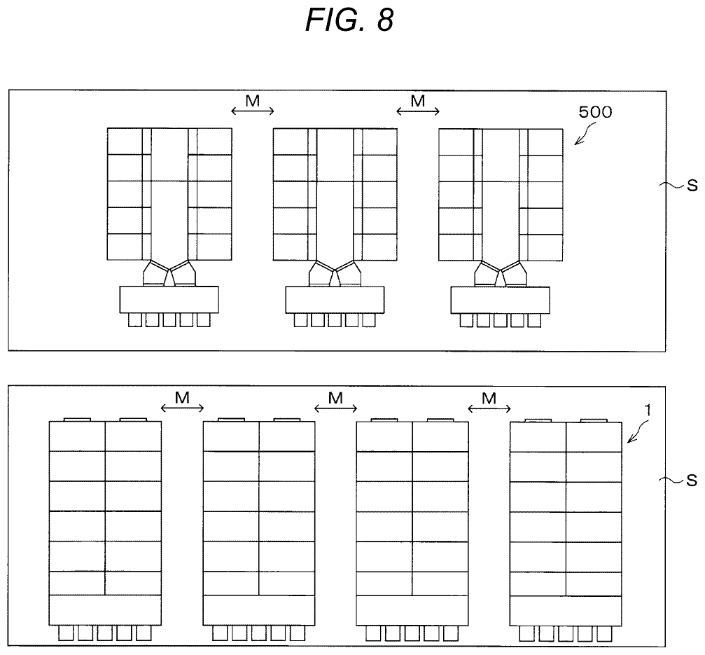

FIG. 8 is an illustrative diagram illustrating a state where the wafer processing apparatus 1 according to the present embodiment and the wafer processing apparatus 500 in the related art are installed in a limited space S of a factory. Here, a predetermined maintenance space M is required between adjacent wafer processing apparatuses. In this case, for example, three wafer processing apparatuses 500 in the related art are installed in the space S, whereas four wafer processing apparatuses 1 according to the present embodiment can be installed in the space S. Therefore, it is possible to improve the productivity per unit area while securing the maintenance space M.

Further, according to the present embodiment, the first processing module 50 and the second transfer module 80 are disposed in this order from the upper side, and the first transfer module 60 and the second processing module 70 are disposed in this order from the upper side. In a side view, the first lower equipment unit 53 is disposed at a height in the upper first processing module 50, and the second lower equipment unit 73 is disposed at a similar height in the lower second processing module 70. Therefore, for example, compared to the case of simply stacking the processing modules as illustrated in FIG. 16, the height can be restricted. As a result, the productivity per unit area is improved while the height of the wafer processing apparatus 1 is restricted. Further, since the height of the wafer processing apparatus 1 is restricted, the accessibility to the equipment above is good, and for example, the maintainability can be improved even if the equipment is heavy.

Further, according to the present embodiment, since the first transfer module 60 includes the magnetically levitated first transfer unit 65, the degree of freedom of the configuration of the first transfer chamber 61 is improved. Further, since the second transfer module 80 includes the magnetically levitated second transfer unit 85, the degree of freedom of the configuration of the second transfer chamber 81 is improved. Since the transfer chambers 61 and 81 can be freely designed in this way, the area occupied by the wafer processing apparatus 1 can be further reduced.

Further, in a case where multiple first transfer units 65 are provided in the first communication transfer space of the first transfer modules 60, for example, even if one first transfer unit 65 fails, another first transfer unit 65 can unload the failed first transfer unit 65. Alternatively, when one first transfer unit 65 fails, a maintenance unit may be inserted into the first communication transfer space and the failed first transfer unit 65 may be carried out.

By using the magnetically levitated first transfer unit 65 as described, the maintenance can be facilitated, and since the second transfer module 80 also has the magnetically levitated second transfer unit 85, similar effects can be obtained.

In the present embodiment, when viewed from a top view, the first transfer system is accommodated in a manner of overlapping the second processing module group, and the second transfer system is accommodated in a manner of overlapping the first processing module group. In this respect, as long as the first transfer system and the second processing module group overlap each other and the second transfer system and the first processing module group overlap each other when viewed from a top view, for example, the first transfer system and the second transfer system may be disposed to overlap each other across a boundary line between the first processing module group and the second processing module group.

Here, for example, in the wafer processing apparatus 500 in the related art illustrated in FIG. 15, it is necessary to prepare a plurality of types (variations) of transfer modules 510 and 511 according to the required number of processing modules 520.

In this respect, according to the present embodiment, the composite module 40 has a configuration in which the first processing module 50, the first transfer module 60, the second processing module 70, and the second transfer module 80 are integrated. Therefore, the types (variations) of the transfer modules 60 and 80 can be unified into one type, and as a result, it is possible to cope with the required number of the processing modules 50 and 70 by increasing or decreasing the number of the composite modules 40. Further, since it is possible to eliminate unnecessary space and layout, it is possible to improve the production efficiency of the wafer processing apparatus 1.

According to the present embodiment, since the opening 63a formed in the front end surface 62a of the first transfer chamber 61 and the opening 63b formed in the rear end surface 62b have the same shape, one composite module 40 can be coupled to any other composite module 40. Therefore, it is possible to further improve the production efficiency of the wafer processing apparatus 1.

Here, for example, in the wafer processing apparatus 500 in the related art illustrated in FIG. 15, since it is necessary to individually connect multiple processing modules 520 to the transfer modules 510 and 511, it takes many man-hours.

In this respect, in the present embodiment, since it is sufficient to couple the composite modules 40 in which the first processing module 50, the first transfer module 60, the second processing module 70, and the second transfer module 80 are integrated, the man-hours can be reduced.

Further, in the present embodiment, since the magnetically levitated first transfer unit 65 provided in the first transfer module 60 can be provided regardless of the configuration of the first transfer chamber 61, the configuration of the first transfer chamber 61 can be made the same. Similarly, since the second transfer module 80 also includes the magnetically levitated second transfer unit 85, the configuration of the second transfer chamber 81 can be made the same. As a result, an order in which the five composite modules 40 are coupled is not limited, and the degree of freedom in producing the wafer processing apparatus 1 is improved.

In the present embodiment, the equipment is disposed in the equipment units 52 and 53 in the first processing module 50, and the equipment is disposed in the equipment units 72 and 73 in the second processing module 70. In this respect, some pieces of equipment of the first processing module 50 and some pieces of equipment of the second processing module 70 may be disposed in at least one of the first region 90 and the second region 91. In this case, the height of the wafer processing apparatus 1 can be further restricted.

Further, some pieces of equipment of the first processing module 50 and some pieces of equipment of the second processing module 70 may be made common and disposed in at least one of the first region 90 and the second region 91. For example, independent equipment that is not directly connected to the processing chambers 51 and 71, such as electric equipment like controllers and power supplies provided in the upper equipment units 52 and 72, a gas box, generators and cooling water supply mechanisms provided in the lower equipment units 53 and 73 may be disposed in the regions 90 and 91. In this case, the height of the wafer processing apparatus 1 can be further restricted. Further, the wafer processing apparatus 1 can be simplified, and an apparatus cost can be reduced.

### Other Embodiments

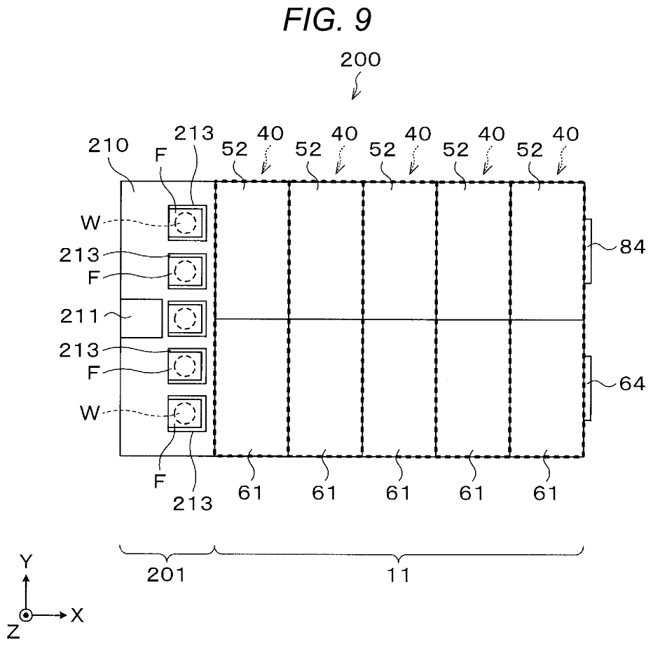

Next, a wafer processing apparatus 200 according to one or more embodiments will be described. FIG. 9 is a plan view illustrating a schematic configuration of the wafer processing apparatus 200. The wafer processing apparatus 200 has a configuration in which a loading and unloading module 201 is provided instead of the normal pressure portion 10 and the load lock modules 20 and 21 of the wafer processing apparatus 1 of the above-described embodiment. That is, the wafer processing apparatus 200 has a configuration in which the loading and unloading module 201 and the pressure-reduced portion 11 are integrally connected. The configuration of the pressure-reduced portion 11 of the wafer processing apparatus 200 and the configuration of the pressure-reduced portion 11 of the wafer processing apparatus 1 are the same.

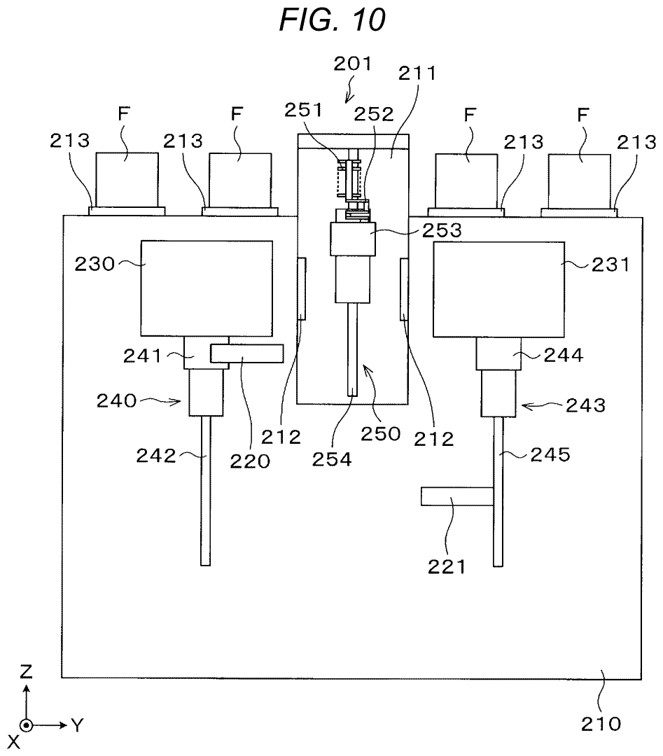

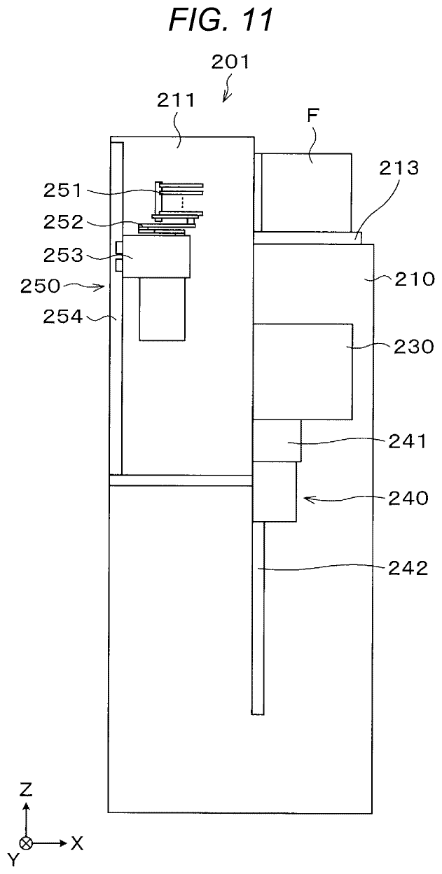

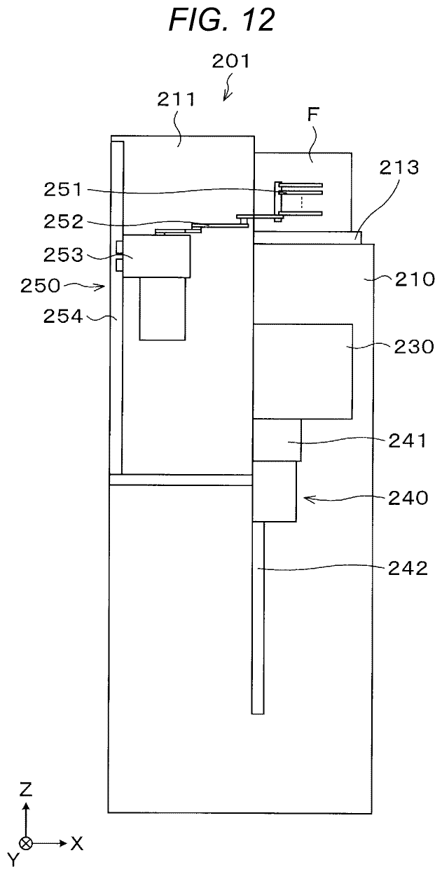

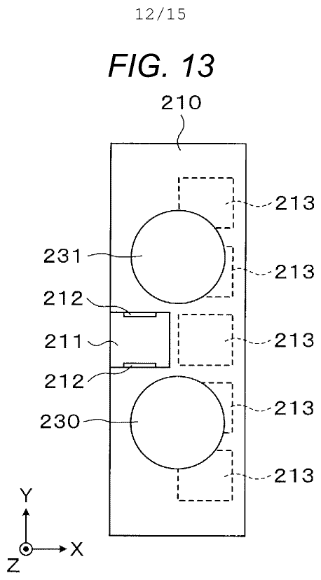

As illustrated in FIGS. 10 to 13, the loading and unloading module 201 has a first transfer chamber (equipment front end module (EFEM)) 210 and a second transfer chamber 211. The first transfer chamber 210 has a rectangular housing, and an inside of the housing is maintained in a pressure-reduced atmosphere. The first transfer chamber 210 is connected to the composite module 40. The second transfer chamber 211 has a rectangular housing, and an inside of the housing is configured to be switched between a normal pressure atmosphere and a pressure-reduced atmosphere. The second transfer chamber 211 is disposed opposite to the composite module 40 (on the X-axis negative direction side) and at a center in the Y-axis direction in the first transfer chamber 210. Further, the second transfer chamber 211 is disposed in an upper portion of the first transfer chamber 210 and protrudes from an upper surface of the first transfer chamber 210. Two gate valves 212 are provided between the first transfer chamber 210 and the second transfer chamber 211 in a lower portion of the second transfer chamber 211. The two gate valves 212 are provided on the Y-axis positive direction side and the Y-axis negative direction side of the second transfer chamber 211.

A stage 213 on which the FOUP F is placed is provided on the upper surface of the first transfer chamber 210. A plurality of, for example, five stages 213 are disposed side by side in the Y-axis direction, closer to the composite module 40 (on the X-axis positive direction side) on the upper surface of the first transfer chamber 210. Among the five stages 213, the stage 213 at the center in the Y-axis direction is disposed facing the second transfer chamber 211.

Two transfer ports 220 and 221 are formed on a side surface of the first transfer chamber 210 closer to the composite module 40 (on the X-axis positive direction side). The first transfer port 220 on the Y-axis negative direction side is formed at a position facing the opening 63a at the front end surface 62a of the forwardmost first transfer chamber 61. The first transfer port 220 and the opening 63a have the same shape, and when the first transfer chamber 210 and the forwardmost first transfer chamber 61 are connected, the first transfer port 220 and the opening 63a are continuous. An interior space of the first transfer chamber 210 communicates with the first communication transfer space of the five first transfer chambers 61.

The second transfer port 221 on the Y-axis positive direction side is formed at a position facing the opening 83a in the front end surface 82a of the forwardmost second transfer chamber 81. The second transfer port 221 and the opening 83a have the same shape, and when the second transfer port 221 and the forwardmost second transfer chamber 81 are connected, the second transfer port 221 and the opening 83a are continuous. The interior space of the first transfer chamber 210 communicates with the second communication transfer space of the five second transfer chambers 81.

Two buffers 230 and 231 configured to temporarily store wafers W are provided inside the first transfer chamber 210. The first buffer 230 is disposed at a position corresponding to the first transfer port 220, and the second buffer 231 is disposed at a position corresponding to the second transfer port 221.

An exhaust port is formed in a bottom surface of the first transfer chamber 210, and the exhaust port is connected to a vacuum pump that includes, for example, a dry pump or a turbo molecular pump. The five first transfer chambers 61 are configured to maintain the first communication transfer space in a pressure-reduced atmosphere by vacuuming the first communication transfer space from the exhaust port. Similarly, the five second transfer chambers 81 are configured to maintain the second communication transfer space in a pressure-reduced atmosphere by vacuuming the second communication transfer space from the exhaust port.

As illustrated in FIGS. 10 to 13, the first buffer 230 is provided with a moving mechanism 240 configured to move the first buffer 230 in a vertical direction. The moving mechanism 240 includes a driving unit 241 provided at the first buffer 230 and a rail 242 extending in the vertical direction. The driving unit 241 moves the first buffer 230 along the rail 242 and rotates the first buffer 230 around a vertical axis. The moving mechanism 240 allows the first buffer 230 to access the first transfer port 220. Further, the first transfer unit 65 of the first transfer module 60 transfers the wafer W to the first buffer 230 through the first transfer port 220.

Further, the second buffer 231 is provided with a moving mechanism 243 configured to move the second buffer 231 in the vertical direction. The moving mechanism 243 includes a driving unit 244 provided at the second buffer 231 and a rail 245 extending in the vertical direction. The driving unit 244 moves the second buffer 231 along the rail 245 and rotates the second buffer 231 around a vertical axis. The moving mechanism 243 allows the second buffer 231 to access the second transfer port 221. Further, the second transfer unit 85 of the second transfer module 80 transfers the wafer W to the second buffer 231 through the second transfer port 221.

A transfer unit 250 configured to transfer the wafer W is provided inside the second transfer chamber 211. The transfer unit 250 includes a transfer arm 251, an expansion mechanism 252, a driving unit 253, and a rail 254. The transfer arm 251 is configured to collectively hold and transfer a plurality of, for example, 25 wafers W (corresponding to one FOUP). The expansion mechanism 252 has, for example, an articulated arm structure, and moves the transfer arm 251 in a horizontal direction. The driving unit 253 moves the transfer arm 251 and the expansion mechanism 252 along the rail 254 extending in the vertical direction, and rotates the transfer arm 251 and the expansion mechanism 252 around a vertical axis. The transfer unit 250 transfers the wafers W between the FOUP F and the first buffer 230 and the second buffer 231.

A lid attaching and detaching mechanism is provided at an upper portion inside the second transfer chamber 211. The lid attaching and detaching mechanism is configured to attach and detach a lid of the FOUP F.

According to the above-described embodiments, since the loading and unloading module 201 has the configuration in which the second transfer chamber 211 and the five stages 213 are provided above the first transfer chamber 210, the area occupied by the loading and unloading module 201 can be reduced. As a result, it is possible to improve the productivity per unit area.

Further, since the inside of the first transfer chamber 210 is maintained in a pressure-reduced atmosphere and the buffers 230 and 231 of the first transfer chamber 210 are accessed by the magnetically levitated transfer units 65 and 85 of the transfer modules 60 and 80, respectively, the load lock module can be omitted. Therefore, the area occupied by the loading and unloading module 201 can be reduced, and the productivity per unit area can be improved.

### Other Embodiments

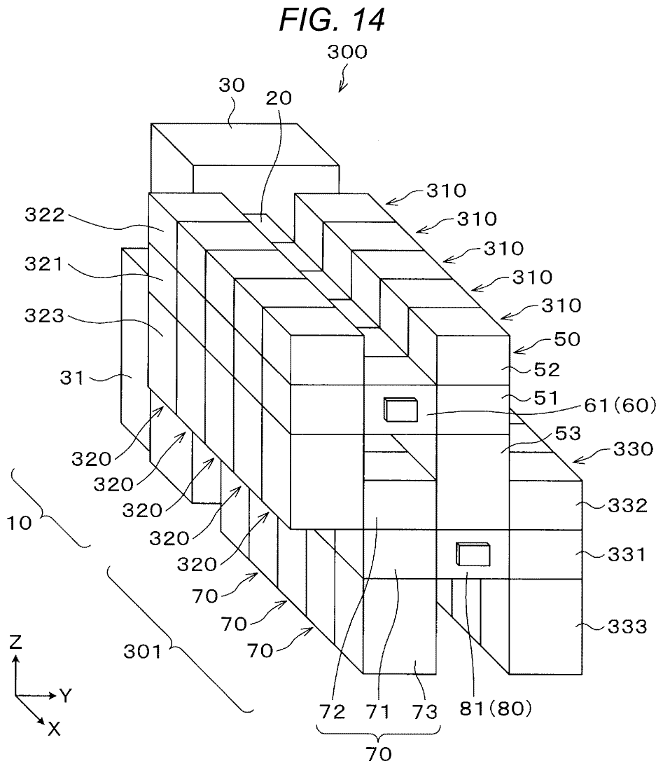

Next, a wafer processing apparatus 300 according to one or more embodiments will be described. FIG. 14 is a perspective view illustrating a schematic configuration of the wafer processing apparatus 300. The wafer processing apparatus 300 has a configuration in which a pressure-reduced portion 301 is provided instead of the pressure-reduced portion 11 of the wafer processing apparatus 1 of the above-described embodiment. A destination to which the pressure-reduced portion 301 is connected may be the normal pressure portion 10 and the load lock modules 20 and 21 of the wafer processing apparatus 1, or may be the loading and unloading module 201 of the wafer processing apparatus 200. In the following description, a configuration in which the normal pressure portion 10 and the load lock modules 20 and 21 are connected to the pressure-reduced portion 301 will be described.

The pressure-reduced portion 301 has a plurality of, for example, five composite modules 310. The five composite modules 310 are coupled side by side in the X-axis direction from the side of the load lock modules 20 and 21.

The composite module 310 includes a third processing module 320 and a fourth processing module 330, in addition to the configuration of the composite module 40. That is, the composite module 310 has a configuration in which the first processing module 50, the first transfer module 60, the second processing module 70, the second transfer module 80, the third processing module 320, and the fourth processing module 330 are integrated.

The third processing module 320 has the same configuration as the first processing module 50, and includes a third processing chamber 321, a third upper equipment unit 322, and a third lower equipment unit 323. The third upper equipment unit 322, the third processing chamber 321, and the third lower equipment unit 323 are stacked in this order from an upper side.

The third processing chamber 321 is connected to the first transfer chamber 61 in the Y-axis direction. That is, the first processing chamber 51 is disposed on the Y-axis positive direction side of the first transfer chamber 61, and the third processing chamber 321 is disposed on the Y-axis negative direction side thereof. Further, the third upper equipment unit 322 is disposed at the same height as the first upper equipment unit 52, and the third lower equipment unit 323 is disposed at the same height as the first lower equipment unit 53. A spatial region is located below the third lower equipment unit 323.

The fourth processing module 330 has the same configuration as the first processing module 50, and includes a fourth processing chamber 331, a fourth upper equipment unit 332, and a fourth lower equipment unit 333. The fourth upper equipment unit 332, the fourth processing chamber 331, and the fourth lower equipment unit 333 are stacked in this order from the upper side.

The fourth processing chamber 331 is connected to the second transfer chamber 81 in the Y-axis direction. That is, the second processing chamber 71 is disposed on the Y-axis positive direction side of the second transfer chamber 81, and the fourth processing chamber 331 is disposed on the Y-axis negative direction side thereof. Further, the fourth upper equipment unit 332 is disposed at the same height as the second upper equipment unit 72, and the fourth lower equipment unit 333 is disposed at the same height as the second lower equipment unit 73. A spatial region is located above the fourth upper equipment unit 332.

The five composite modules 310 are coupled side by side in a coupling direction (the X-axis direction) from the side of the load lock modules 20 and 21. In the five composite modules 310, the five third processing modules 320 are disposed side by side in the X-axis direction, and constitute a third processing module group in the present disclosure. Similarly, the five fourth processing modules 330 are disposed side by side in the X-axis direction, and constitute a fourth processing module group in the present disclosure.

According to the embodiment described above, since one composite module 310 includes four processing modules 50, 70, 320, and 330, the productivity can be improved. The number of processing modules in the composite module is not limited to two or four in the above-described embodiment, and may be freely set. Further, either the third processing module 320 or the fourth processing module 330 may be provided.

### Other Embodiments

Although the composite modules 40 and 310 are coupled in the wafer processing apparatuses 1, 200, and 300 of the above-described embodiments, the processing module and the transfer module may not be combined into a composite module. That is, the processing module and the transfer module may be provided independently of each other.

Although the opening 63b of the rear end surface 62b of the rearmost first transfer chamber 61 is closed by the plate 64 in the first transfer system of the embodiment described above, a pit-in chamber may be connected to the rearmost first transfer chamber 61. For example, a maintenance unit is accommodated inside the pit-in chamber. The maintenance unit is a rescue unit configured to replace the first transfer unit 65 that is in failure. Alternatively, the maintenance unit is a cleaning unit configured to clean the first communication transfer space of the first transfer chambers 61.

Another processing chamber, for example, a post-processing chamber for performing ashing processing on the wafer W after plasma processing may be connected to the rearmost first transfer chamber 61. Further, similarly, in the second transfer system, instead of the plate 84, a pit-in chamber, a post-processing chamber, or the like may be provided.

Although the plasma processing is performed on the wafer W in the processing chambers 51, 71, 321, and 331 in the embodiments described above, other processing may be performed. For example, post-processing such as ashing processing described above may be performed in the processing chambers 51, 71, 321, and 331. Alternatively, the pit-in chamber described above may be provided instead of the processing chambers 51, 71, 321, and 331.

Although lengths of the processing chambers 51, 71, 321, and 331 in the X-axis direction are the same in the above-described embodiments, the lengths may be different. In the processing chambers 51, 71, 321, and 331, for example, when performing batch processing on four wafers W, the lengths of the processing chambers 51, 71, 321, and 331 in the X-axis direction are increased. Meanwhile, for example, when performing ashing processing, sizes of the processing chambers 51, 71, 321, and 331 may be reduced, and the lengths of the processing chambers 51, 71, 321, and 331 in the X-axis direction are reduced.

Although the magnetically levitated transfer units 65 and 85 are provided in the communication transfer spaces of the five transfer chambers 61 and 81 in the above-described embodiments, instead of the transfer units 65 and 85, a fixed transfer unit may be provided. The transfer unit is fixed to one of the five transfer chambers 61 and 81. The fixed transfer unit includes an arm configured to hold and transfer the wafer W. The number of the fixed transfer units in the communication transfer space is freely set, and may be two or more.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The effects described herein are merely illustrative or exemplary, and are not limited. In other words, the technique according to the present disclosure may have other effects apparent to those skilled in the art from the description herein, in addition to or in place of the effects described above.

The following configuration examples also fall within the technical scope of the present disclosure.
(1) A substrate processing apparatus for processing a substrate, the substrate processing apparatus including:
   a first processing module group including one or more first processing modules;
   a first transfer module connected to the first processing module;
   a second processing module group including one or more second processing modules; and
   a second transfer module connected to the second processing module, in which the first transfer module is disposed above the second processing module, and
   the second transfer module is disposed below the first processing module.
(2) The substrate processing apparatus according to (1), in which
   the first processing module includes a first processing chamber,
   the first transfer module includes a first transfer chamber,
   the second processing module includes a second processing chamber,
   the second transfer module includes a second transfer chamber,
   a plurality of the first processing chambers are disposed side by side in a first direction that is a horizontal direction,
   the first transfer chambers are disposed side by side in the first direction and are connected to the plurality of the first processing chambers in a second direction orthogonal to the first direction,
   a plurality of the second processing chambers are disposed side by side in the first direction, and
   the second transfer chambers are disposed side by side in the first direction and are connected to the plurality of the second processing chambers in the second direction.
(3) The substrate processing apparatus according to (1) or (2), in which
   the first transfer module includes a magnetically levitated first transfer unit.
(4) The substrate processing apparatus according to any one of (1) to (3), in which
   the second transfer module includes a magnetically levitated second transfer unit.
(5) The substrate processing apparatus according to (1) or (2), in which
   the first transfer module includes a fixed first transfer unit.
(6) The substrate processing apparatus according to any one of (1), (2), or (5), in which
   the second transfer module includes a fixed second transfer unit.
(7) The substrate processing apparatus according to any one of (1) to (6), further including:
   a third processing module group including one or more third processing modules connected to the first transfer module.
(8) The substrate processing apparatus according to any one of (1) to (7), further including:
   a fourth processing module group including one or more fourth processing modules connected to the second transfer module.
(9) The substrate processing apparatus according to any one of (1) to (8), in which
   a first region is located on a side of the first processing module below the first transfer module,
   a second region is located on a side of the second processing module below the second transfer module, and
   equipment of at least one of the first processing module and the second processing module is disposed in at least one of the first region and the second region.
(10) The substrate processing apparatus according to any one of (1) to (8), in which
   a first region is located on a side of the first processing module above the first transfer module,
   a second region is located on a side of the second processing module above the second transfer module, and
   equipment of at least one of the first processing module and the second processing module is disposed in at least one of the first region and the second region.
(11) The substrate processing apparatus according to any one of (1) to (10), in which
   the first transfer module includes a first transfer chamber,
   the second transfer module includes a second transfer chamber,
   the first processing module, the first transfer module, the second processing module, and the second transfer module are integrated to form a composite module, and
   the first transfer chambers adjacent to each other are connected and the second transfer chambers adjacent to each other are connected so that a plurality of the composite modules are coupled.
(12) The substrate processing apparatus according to any one of (1) to (11), in which
   an inside of the first transfer module is maintained in a pressure-reduced atmosphere,
   an inside of the second transfer module is maintained in a pressure-reduced atmosphere, and
   the substrate processing apparatus includes
      a first transfer chamber connected to the first transfer module and the second transfer module, an inside of the first transfer chamber being maintained in a pressure-reduced atmosphere, and
      a second transfer chamber configured to be switchable between a normal pressure atmosphere and a pressure-reduced atmosphere and connected to the first transfer chamber.
(13) The substrate processing apparatus according to any one of (1) to (11), in which
   an inside of the first transfer module is maintained in a pressure-reduced atmosphere,
   an inside of the second transfer module is maintained in a pressure-reduced atmosphere, and
   the substrate processing apparatus includes
      a first load lock module configured to be switchable between a normal pressure atmosphere and a pressure-reduced atmosphere and connected to the first transfer module,
      a second load lock module configured to be switchable between a normal pressure atmosphere and a pressure-reduced atmosphere and connected to the second transfer module, and
      a loader module connected to the first load lock module and the second load lock module, an inside of the loader module being maintained in a normal pressure atmosphere.

1. A substrate processing apparatus for processing a substrate, the substrate processing apparatus comprising:
a first processing module group including a plurality of first processing modules;
a plurality of first transfer modules, each first transfer module being connected to a respective one of the plurality of first processing modules;
a second processing module group including a plurality of second processing modules; and
a plurality of second transfer modules, each second transfer module being connected to a respective one of the plurality of second processing modules, wherein
the first transfer modules are disposed above the plurality of second processing modules, and
the second transfer modules are disposed below the plurality of first processing modules.

2. The substrate processing apparatus according to claim 1, wherein:
each first processing module includes a first processing chamber,
the first transfer module includes a first transfer chamber,
each second processing module includes a second processing chamber,
the second transfer module includes a second transfer chamber,
the plurality of the first processing chambers are disposed side by side in a first direction that is a horizontal direction,
the first transfer chambers are disposed side by side in the first direction and are connected to the plurality of the first processing chambers in a second direction orthogonal to the first direction,
a plurality of the second processing chambers are disposed side by side in the first direction, and
the second transfer chambers are disposed side by side in the first direction and are connected to the plurality of the second processing chambers in the second direction.

3. The substrate processing apparatus according to claim 1, wherein
each first transfer module includes a magnetically levitated first transfer unit.

4. The substrate processing apparatus according to claim 1, wherein
each second transfer module includes a magnetically levitated second transfer unit.

5. The substrate processing apparatus according to claim 1, wherein
each first transfer module includes a fixed first transfer unit.

6. The substrate processing apparatus according to claim 1, wherein
each second transfer module includes a fixed second transfer unit.

7. The substrate processing apparatus according to claim 1, further comprising:
a third processing module group including one or more third processing modules connected to the plurality of first transfer modules.

8. The substrate processing apparatus according to claim 1, further comprising:
a fourth processing module group including one or more fourth processing modules connected to the plurality of second transfer modules.

9. The substrate processing apparatus according to claim 1, wherein
a first region is located on a side of the plurality of first processing modules below the plurality of first transfer modules,
a second region is located on a side of the plurality of second processing modules below the plurality of second transfer modules, and
equipment of at least one of the plurality of first processing modules and the plurality of second processing modules is disposed in at least one of the first region and the second region.

10. The substrate processing apparatus according to claim 1, wherein
a first region is located on a side of the plurality of first processing modules above the plurality of first transfer modules,
a second region is located on a side of the plurality of second processing modules above the plurality of second transfer modules, and
equipment of at least one of the plurality of first processing module and the plurality of second processing module is disposed in at least one of the first region and the second region.

11. The substrate processing apparatus according to claim 1, wherein
each first transfer module includes a first transfer chamber,
each second transfer module includes a second transfer chamber,
the plurality of first processing modules, the plurality of first transfer modules, the plurality of second processing modules, and the plurality of second transfer modules are integrated to form a composite module, and
the first transfer chambers adjacent to each other are connected and the second transfer chambers adjacent to each other are connected so that a plurality of the composite modules are coupled.

12. The substrate processing apparatus according to claim 1, wherein
an inside of each first transfer module is maintained in a pressure-reduced atmosphere,
an inside of each second transfer module is maintained in a pressure-reduced atmosphere, and
the substrate processing apparatus further_includes:
a plurality of first transfer chambers, each first transfer chamber being connected to a respective one of the plurality of first transfer modules and a respective one of the plurality of second transfer modules, an inside of each first transfer chamber being maintained in a pressure-reduced atmosphere, and
a plurality of second transfer chambers, each second transfer chamber being configured to be switchable between a normal pressure atmosphere and a pressure-reduced atmosphere and connected to a respective one of the plurality of first transfer chambers.

13. The substrate processing apparatus according to claim 1, wherein
an inside of each first transfer module is maintained in a pressure-reduced atmosphere,
an inside of each second transfer module is maintained in a pressure-reduced atmosphere, and
the substrate processing apparatus further includes:
a first load lock module configured to be switchable between a normal pressure atmosphere and a pressure-reduced atmosphere and connected to the plurality of first transfer modules,
a second load lock module configured to be switchable between a normal pressure atmosphere and a pressure-reduced atmosphere and connected to the plurality of second transfer modules, and
a loader module connected to the first load lock module and the second load lock module, an inside of the loader module being maintained in a normal pressure atmosphere.

14. A method of producing a substrate processing apparatus, the method comprising:
providing a first processing module group including a plurality of first processing modules;
providing a second processing module group including a plurality of second processing modules;
connecting a plurality of first transfer modules to the first processing module group such that the plurality of first transfer modules are disposed above the second processing module group; and
connecting a plurality of second transfer modules to the second processing module group such that the plurality of second transfer modules are disposed below the first processing module group.

15. The method according to claim 14, further comprising magnetically levitating a first transfer unit in each of the plurality of first transfer modules.

16. The method according to claim 14, further comprising integrating the first processing module group, the plurality of first transfer modules, the second processing module group, and the plurality of second transfer modules to form a composite module, and coupling a plurality of the composite modules side by side.

17. A method of processing a substrate, the method comprising:
transferring the substrate from a normal pressure portion to a pressure-reduced portion via a load lock module;
transferring the substrate using a first transfer module to one or more first processing modules in a first processing module group, wherein the first transfer module is disposed above a second processing module group;
processing the substrate in the one or more first processing modules under a pressure-reduced atmosphere;
transferring the substrate using a second transfer module to one or more second processing modules in the second processing module group, wherein the second transfer module is disposed below the first processing module group; and
processing the substrate in the one or more second processing modules under a pressure-reduced atmosphere.

18. The method according to claim 17, wherein the processing in the one or more first processing modules includes plasma processing.

19. The method according to claim 17, further comprising switching an inside of the load lock module between a normal pressure atmosphere and a pressure-reduced atmosphere.

20. The method according to claim 17, further comprising transferring the substrate back to the normal pressure portion after processing.
